(19) United States
(12) Patent Application Publication
(10) Pub. No.: US 2007/0240750 A1
(43) Pub. Date: Oct. 18, 2007

(54) Nanoscale thermoelectrics by bulk processing

(76) Inventors: G. Jeffrey Snyder, Altadena, CA (US); Teruyuki Ikeda, Pasadena, CA (US); Sossina M. Haile, Altadena, CA (US); Vilupanur A. Ravi, Claremont, CA (US)

Correspondence Address: Seth Z. Kalson;c/o Intellevate, P.O. Box 52050, Minneapolis, MN, 55402, US

(21) Appl. No.: 11/714,694

(22) Filed: Mar. 5, 2007

Related U.S. Application Data
(60) Provisional application No. 60/779,647, filed on Mar. 6, 2006.

(51) Int. Cl. H01L 35/00

(52) U.S. Cl. 136/201; 136/238; 419/29

(57) ABSTRACT

A thermoelectric having self-assembled structures, where the structures may be lamellae or dendrites. For some embodiments, the self-assembled structures are obtained by melting a mixture of Pb, Te, and Sb; cooling; and then annealing. During this process, a metastable alloy is formed, which decomposes into lamellae structures of PbTe and Sb₂Te₃. Other embodiments are described and claimed.

### BENEFIT OF PROVISIONAL APPLICATION

This application claims the benefit of U.S. Provisional Application No. 60/779,647, filed 6 Mar. 2006.

### GOVERNMENT INTEREST

The U.S. Government has certain rights in this invention pursuant to Grant No. DMR0080065 awarded by the National Science Foundation, and Grant No. N000140610364 awarded by the Office of Naval Research.

### FIELD

The present invention relates to thermoelectric materials.

### BACKGROUND

Thermoelectric devices may be either thermal-to-electric generators, or Peltier coolers. Thermoelectric generators provide electrical power in response to a temperature gradient. Two dissimilar thermoelectric materials may be placed in contact with each other to form a junction, so that the junction is at a temperature higher than the temperature of the other ends of the two thermoelectric materials. A voltage difference (the thermoelectric electromotive force) is generated between the two lower-temperature ends, which may be utilized to generate electrical power.

In a Peltier cooler, electric current is forced through the junction of two dissimilar thermoelectric materials by means of a DC (Direct Current) current source. The current through this junction absorbs or releases heat providing cooling or heating.

For efficient thermoelectric devices for both space and terrestrial applications, materials with a high thermoelectric figure of merit are desirable. A common figure of merit for a thermoelectric material, denoted by z, is defined as z≡S²σ/κ, where S is the Seebeck coefficient, σ is the electrical conductivity, and κ is the thermal conductivity. The Seebeck coefficient for a thermoelectric material is the voltage difference per degree Kelvin, and the dimension of z is in units of reciprocal Kelvin. Another figure of merit may be defined as zT, where T is the temperature difference in Kelvin, so that zT is a dimensionless quantity.

Materials investigated and optimized over the past 50 years have been conventional, simple semiconductors. Examples include alloys of bismuth telluride, lead telluride, and silicon germanium, with the best of these exhibiting zT values of no greater than approximately 1. Recently, this zT barrier has been broken, so that zT>2 has been achieved in thin film superlattices or quantum well materials with feature sizes of several to tens of nanometers. (See, for example, Caylor, J. C., Coonley, K., Stuart, J., Colpitts, T., and Venkatasubramanian, R. Applied Physics Letters 2005, 87, 23105; Venkatasubramanian, R.; Siivola, E.; Colpitts, T.; O'Quinn, B. Nature 2001, 413, 597-602; and Harman, T. C.; Taylor, P. J.; Walsh, M. P.; LaForge, B. E. Science 2003, 297, 2229-2232.) The first significant result has been that of Venkatasubramanian (2001) who demonstrated zT=2.4 using Bi₂Te₃—Sb₂Te₃ quantum well superlattices with 6 nm periodicity. Harman and coworkers prepared quantum dot superlattices in the PbTe-PbSeTe system (described as PbSe nanodots embedded in a PbTe matrix) and demonstrated zT values of 1.6.

Despite the high zT of such thermoelectrics, the performance of devices utilizing superlattice materials has not yet surpassed the performance of bulk Bi₂Te₃ based devices. This is due to the small size of the thermoelectric elements that currently are achieved from ‘top-down’ fabrication methods, which imply a large, relative contribution of electrical and thermal contact resistances. Accordingly, it is of utility to provide nanostructured thermoelectric elements that could be manufactured on the mm³ scale as opposed to the μm³ scale.

### BRIEF DESCRIPTION OF THE DRAWINGS

FIGS. 1A through 1C illustrate the microstructure of some embodiments of the present invention in which Pb₂Sb₆Te₁₁ is transformed into PbTe and Sb₂Te₃ rich regions by annealing. (The lighter regions are PbTe, and the darker regions are Sb₂Te₃.)

FIG. 2 illustrates the average layer period of PbTe and Sb₂Te₃ decomposed regions according to some embodiments of the present invention, showing the decrease in lamellae spacing as the temperature or time of anneal is reduced. (Error bars show the standard deviation of lamellar spacing distribution.)

FIGS. 3A and 3B illustrate simplified flow diagrams according to some embodiments of the present invention.

FIGS. 4A through 4B illustrate microstructures near the center of Te—Sb—Pb alloys solidified by air cooling according to some embodiments of the present invention. The compositions are Te-36 at. % Sb-5 at. % Pb (FIG. 4A); Te-31.5 at. % Sb-10.5 at. % Pb (FIG. 4B); and Te-24 at. % Sb-20 at. % Pb (FIG. 4C).

FIGS. 5A through 5C illustrate microstructures near the center of Te—Sb—Pb alloys solidified by water quenching according to some embodiments of the present invention. The compositions are Te-36 at. % Sb-5 at. % Pb (FIG. 5A); Te-31.5 at. % Sb-10.5 at. % Pb (FIG. 5B); and Te-24 at. % Sb-20 at. % Pb (FIG. 5C).

FIG. 6 illustrates thermal conductivity as a function of inter-lamellar spacing (period) according to an embodiment of the present invention.

FIG. 7 illustrates the cooling rate dependence of average secondary dendrite arm spacing (SDAS) and average inter-lamellar spacing (ILS) for some embodiments of the present invention. (Broken lines are the fits to the experimental data.)

FIG. 8 illustrates microstructures according to an embodiment of the present invention for a cooling rate of approximately 1.4×10⁴ K/s achieved by injection molding. The light structures are PbTe and the dark structures are Pb₂Sb₆Te₁₁.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

In the description that follows, various experimental results are described, and various explanations and theories are proposed to explain some of these results. However, it should be appreciated that these experimental results and explanations are given only to provide insight into some of the described embodiments. Other embodiments may yield different experimental results, and other theories may perhaps be proposed for explaining various observed results. Accordingly, it should be remembered that the invention is defined and limited only by the claims concluding this description of embodiments, and not by the experimental results and theories proposed regarding this description of embodiments.

Fabricating thermoelectric material according to some embodiments of the present invention comprises rapid solidification and decomposition of thermoelectric composites, resulting in self-assembled nanostructured thermoelectrics in bulk volumes. Random, self-assembled structures with nanometer to submicron feature sizes are expected to result in quantum confinement effects, thereby increasing the Seebeck coefficient S; and are expected to increase phonon scattering, thereby decreasing the thermal conductivity κ. This is expected to result in enhancements to zT.

Consider the pseudo binary system PbTe—Sb₂Te₃ of the two immiscible thermoelectric materials PbTe and Sb₂Te₃. While the phase diagram of the resulting pseudo-binary system may be in dispute, it is known that a moderately deep eutectic occurs at approximately 40 mol % PbTe with a melting temperature of approximately 585 Celsius. The ternary compound Pb₂Sb₆Te₁₁ may be formed in the binary system PbTe—Sb₂Te₃, and is close to the eutectic composition. The authors of these letters patent have found that Pb₂Sb₆Te₁₁ is metastable and decomposes into submicron-scale lamellae of PbTe and Sb₂Te₃, where the lamellar spacing may be controlled by adjusting the time and (or) temperature of the transformation process.

Pb₂Sb₆Te₁₁ was prepared by high temperature direct synthesis. Lead (99.999% pure), Antimony (99.99% pure), and Tellurium (99.999% pure) were loaded into 12 mm diameter quartz ampoules in the required stoichiometric ratio and then sealed under a vacuum of approximately 3×10⁻⁵ torr to prevent oxidation at high temperatures. Samples were reacted in a high temperature single zone vertical furnace for 24 hours at 750° C. Alloys were subsequently water quenched and then annealed at selected temperatures, from 200° C. to 500° C., for periods of 15 minutes to 5 days

The resulting ingots were cut, mounted in epoxy pucks, and polished with 0.3 μm Al₂O₃ paste. The microstructures were observed using a field emission-scanning electron microscope equipped with a Robinson backscattered electron (BSE) detector for its high compositional contrast capabilities. The accelerating voltage was 20 kV. The chemical compositions of the constituent phases in each alloy were measured using an energy dispersive X-ray spectrometer (EDS) or using a wavelength dispersive X-ray spectrometer (WDS). For the WDS measurements, Sb, Te, and Pb samples were used as standards for ZAF conversion from intensities of Pb M_{α}, Sb L_{α}, and Te L_{α} to concentrations. The crystallographic orientations in the microstructures were determined using the electron backscatter diffraction technique (EBSD). For these measurements, the surfaces of the samples were finally polished with colloidal silica (50 nm). The operating voltage of the electron microprobe was 20 kV. The surface of the samples was inclined at 70° to the vertical direction with respect to the electron beam. Electron backscatter patterns over areas of 11.2×5 μm² were mapped in steps of 0.2×0.2 μm² and analyzed using a commercial software package.

Features of the microstructure, including lamellar spacing, and volume fractions of the resulting phases, were quantified using image analysis software. To determine the distribution of lamellar spacing of the resulting embodiments, the distances between all neighboring lamellae in at least seven SEM images (one image typically includes 200-600 lamellae) were measured. X-ray diffraction (XRD) was performed on powder samples to identify phases and their crystal structure.

The pseudo-binary system examined here is comprised of two largely immiscible compounds: PbTe and Sb₂Te₃, where both compounds individually exhibit good thermoelectric properties. The phase Pb₂Sb₆Te₁₁ has a crystal structure distinct from that of PbTe and Sb₂Te₃, but is not found in some of the phase diagrams because it is metastable. Two invariant reactions are of relevance: a peritectic reaction, L+PbTe=Pb₂Sb₆Te₁₁; and a eutectic reaction, L=Pb₂Sb₆Te₁₁+Sb₂Te₃.

Even without significant effort to cool rapidly, the mixed crystalline phase Pb₂Sb₆Te₁₁ forms. Compositional analysis using EDS indicated that the majority phase has the composition Pb_{9.66}Sb_{32.64}Te_{57.69}, very near the reported eutectic composition Pb_{9.84}Sb_{32.12}Te_{58.03}. The Pb₂Sb₆Te₁₁ phase is greater than 98 vol % of the sample. The remaining 2 vol % or less is composed of PbTe (containing 6 at % Sb), visible as a bright phase in electron back-scatter images, and a darker phase that is Sb₂Te₃ (containing 2-3 at % Pb). These compositions were also observed from off-eutectic solidification. The PbTe phases in this composition may have a range of microstructural morphologies ranging from globular to dendritic, with limited regions of the fine microstructure.

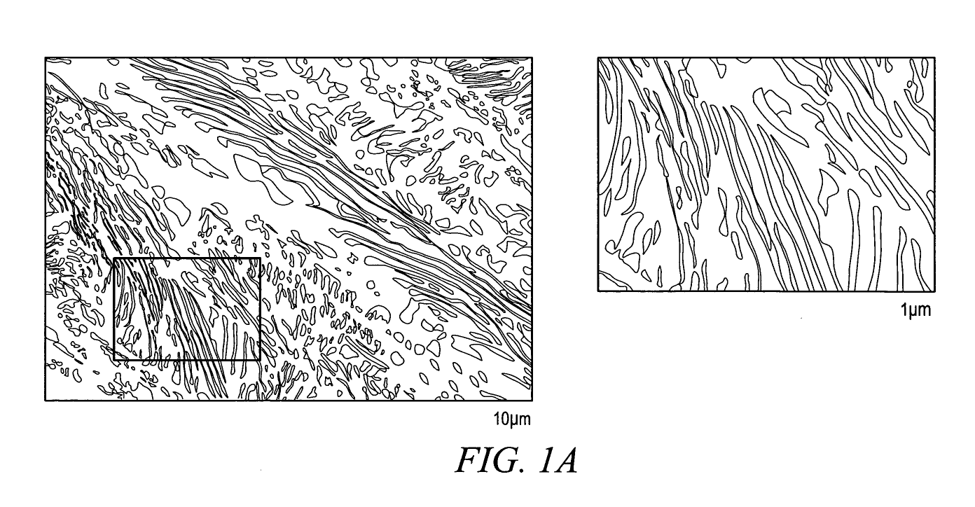

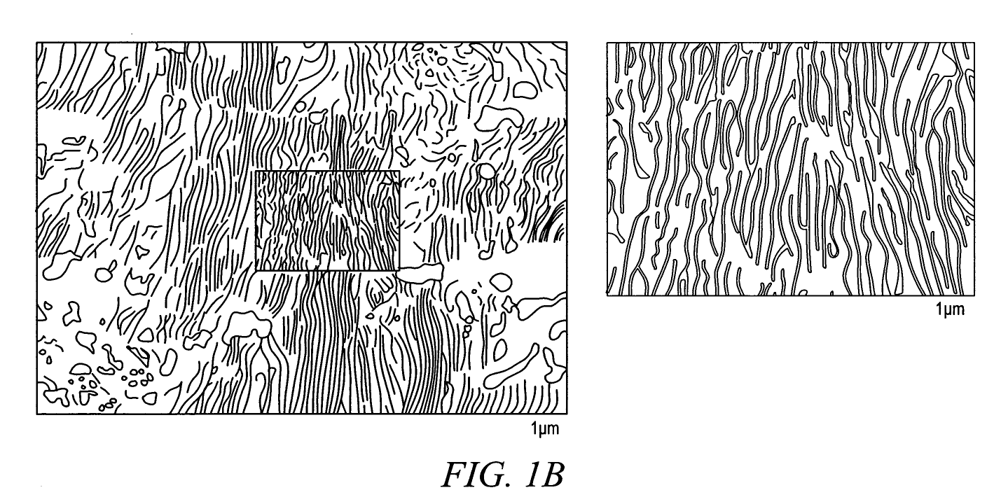

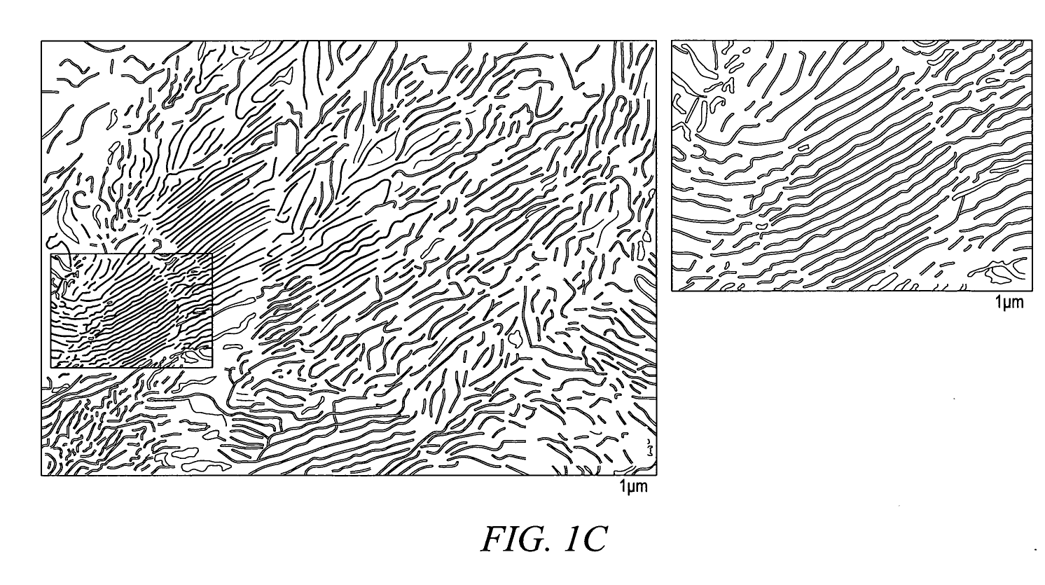

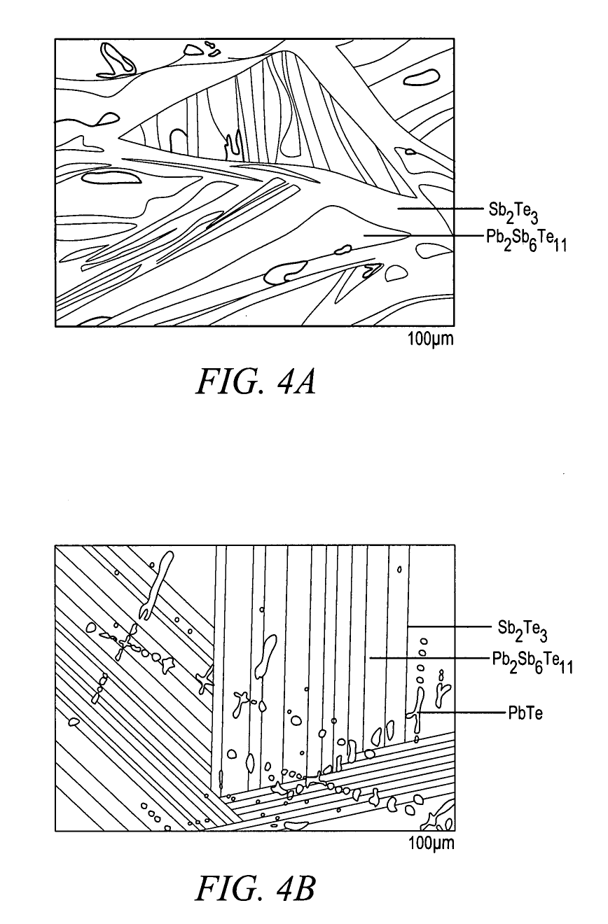

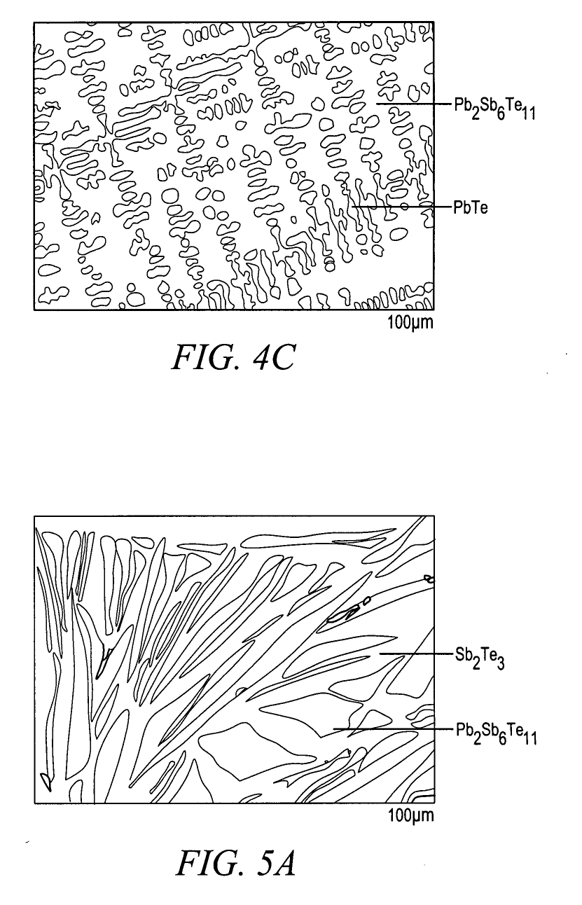

Upon annealing, the Pb₂Sb₆Te₁₁ phase decomposes into submicron scale layers of PbTe and Sb₂Te₃. FIGS. 1A, 1B, and 1C illustrate microstructures of three embodiments imaged by a scanning electron microscope, where the embodiments illustrated in FIGS. 4A through 4B were annealed for 5 days at 500° C., 400° C., and 300° C., respectively. The lighter regions are PbTe, and the darker regions are Sb. A 5 day anneal at 500° C. completely decomposes Pb₂Sb₆Te₁₁ into a lamellar structure. (See FIG. 1A). These decomposition products are well crystallized with the expected PbTe and Sb₂Te₃ structures as confirmed by XRD.

The lamellae in FIGS. 1A and 1B occur in regions, loosely termed grains (with grain size on the order of 10-30 μm), within which the lamellae are all in the same direction and uniformly spaced. The lamellar spacing for different grains appears to vary considerably. The apparent variation in lamellar spacing from grain to grain is largely due to differences in orientation of individual grains. For these particular embodiments, lamellae that happen to be perpendicular to the specimen surface have the smallest spacing while those that are nearly coplanar to the specimen surface appear to have a much larger spacing. Thus, not only is the interlamellar spacing narrower than suggested by the images, the true interlamellar spacing is closest to that seen in the grains with the finest microstructure. Assuming a random orientation of grains, the average layer spacing (defined as the full wavelength of compositional variation) and the distribution width were modeled, and are discussed below.

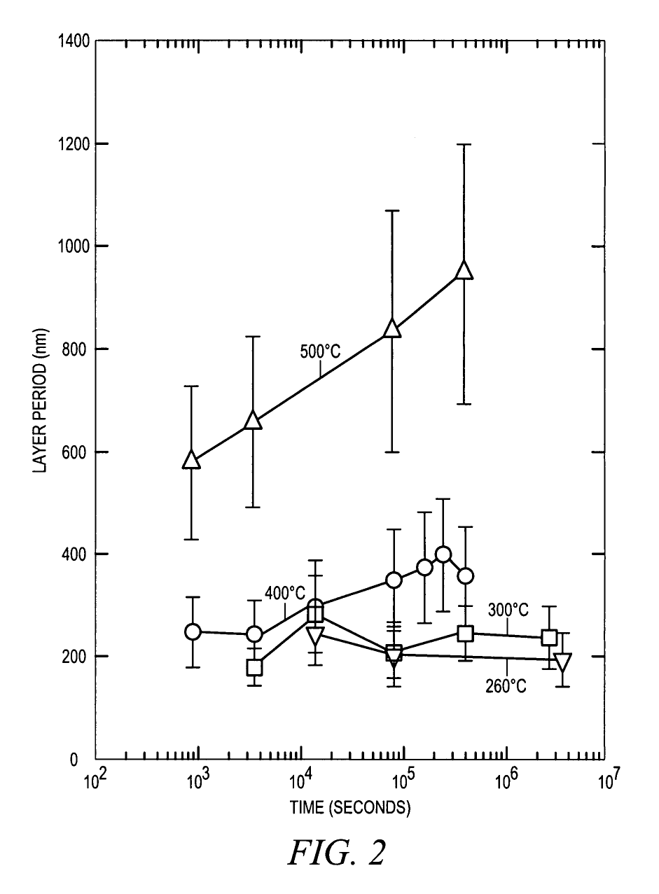

The spacings between the lamellae noticeably increased with both the temperature and time of annealing, whereas the amount of remaining Pb₂Sb₆Te₁₁ decreased. This is illustrated in FIG. 2, showing the average layer period of Sb₂Te₃ and PbTe decomposed regions. Error bars in FIG. 2 show the standard deviation of lamellar spacing distribution for the particular embodiments described. Accordingly, the finest interlamellar spacing of 179 nm was observed after a 3 hr anneal at 300° C. This spacing implies, on the basis of the overall alloy composition and by image analysis, Sb₂Te₃ layers that are 140 nm in thickness and PbTe layers that are 39 nm in thickness. For a eutectoid decomposition process, the layer spacing, λ, is expected to change with time t and absolute temperature T according to

$$λ - {λ}_{0} = \frac{KDt}{T}$$

where D is the diffusion coefficient and K is a geometric factor. The layer spacing at the initiation of growth, λ₀, is expected to be given by

$${λ}_{0} = \frac{4 γ {T}_{E} {V}_{m}}{Δ H Δ T} ,$$

as derived from the minimum thermodynamic size at nucleation. Here, γ is the surface energy, T_{E} is the eutectoid invariant temperature, ΔT and ΔH are the temperature and enthalpy difference of the supercooled material at the point of nucleation compared to T_{E}, and Vₘ is the molar volume. The increase in interlamellar spacing with time as illustrated in FIG. 2 is clearly expected from these relationships, although the linear dependence with time is not verified. Its increase with temperature suggests that λ₀ strongly depends on temperature, most likely via its dependence on ΔT.

An examination of partially decomposed regions for some embodiments indicates that the lamellae grow into the un-decomposed Pb₂Sb₆Te₁₁ in a typical eutectoid manner such that the lamellae are preferentially oriented perpendicular to the interface between the un-decomposed and decomposed regions. The grain boundaries of the un-decomposed Pb₂Sb₆Te₁₁, which may contain a thin layer Sb₂Te₃ as a grain boundary phase, appear to nucleate as well as stop the growth of the lamellae. For some embodiments, it is also found that the PbTe lamellae have a cubic structure (rock salt type), and that the Sb₂Te₃ lamellae have a rhombohedra structure.

The PbTe—Pb₂Sb₆Te₁₁—Sb₂Te₃ system displays rather remarkable features in the crystallographic orientation between component phases, as determined by the EBSD analyses. Within the decomposed regions, EBSD analysis shows that adjacent Sb₂Te₃ and PbTe lamellae are oriented such that the <001> basal planes of Sb₂Te₃ are parallel to one of the <111> planes of PbTe. These correspond to the close-packed Te planes in the respective structures, and the lattice mismatch is only about 6%. The lamellae planes (the interface between the lamellar Sb₂Te₃ and PbTe phases) have little preferred crystallographic orientation. Thus the growth of the lamellae may occur in different crystallographic orientations. Moreover, there does not appear to be an obvious correlation between the crystallographic orientation of un-decomposed Pb₂Sb₆Te₁₁ and that of the product phases. This raises the possibility that the lamellar growth direction, and hence orientation, may be controlled via further control of the crystallization conditions by employing, for example, a temperature gradient or heterogeneous nucleation sites.

That the decomposition phases Sb₂Te₃ and PbTe are highly oriented with respect to one another, a characteristic typical of epitaxial crystal growth, suggests the presence of clean, atomically precise interfaces. The presence of such interfaces within nanoscale superlattices may be critical to the high performance of nanostructured thermoelectrics.

For utilization in thermoelectric devices, for some embodiments the charge carrier concentration of this material may be further optimized. The samples described above are p-type with high carrier concentration, having a Seebeck coefficient of 30 μV/K and electrical resistivity of 4×10⁻⁴ Ω cm. The high carrier concentration may further make the thermal conductivity large due to the electronic contribution to thermal conductivity from the Wiedeman-Franz law. Thus, for some embodiments the p-type carrier concentration may be reduced through chemical doping. Preliminary investigations show that at least some reduction in carrier concentration is possible.

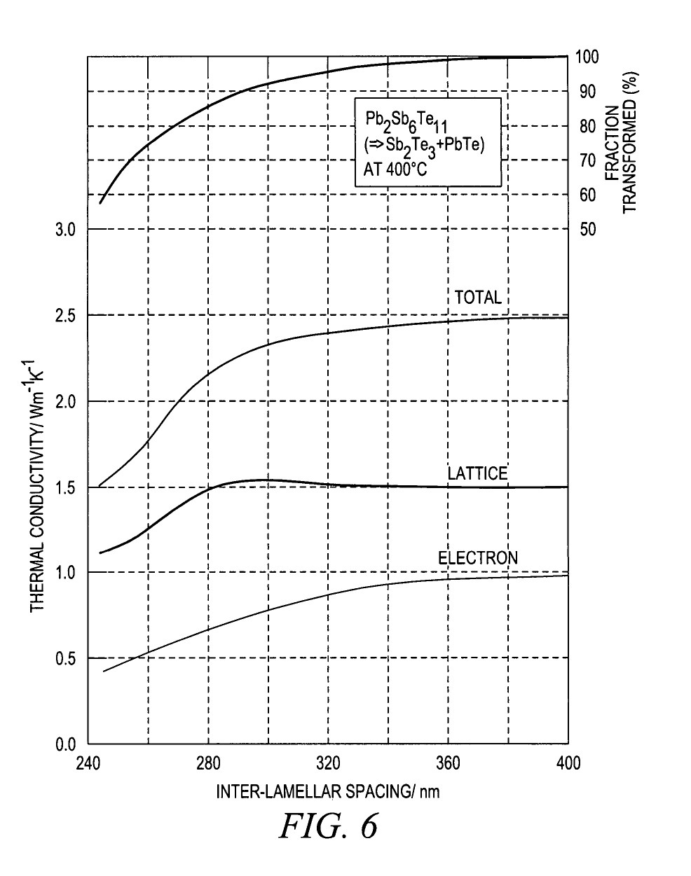

As Pb₂Sb₆Te₁₁ partitions to PbTe and Sb₂Te₃ and subsequently coarsens, thermal conductivity measurements were obtained with a laser flash diffusivity system at 400° C. These results are provided in FIG. 6, showing thermal conductivity as a function of inter-lamellar spacing (period) at 400° C. in PbTe/Sb₂Te₃ composites. The lattice thermal conductivity clearly shows a reduction starting at about 300 nm periods, dropping by 25% at 240 nm periods. The electronic contribution is calculated based on the volume fraction of untransformed Pb₂Sb₆Te₁₁ and transformed PbTe/Sb₂Te₃ composite. Upon nucleation, the lamellae thickness is 250 nm (PbTe 60 nm, Sb₂Te₃ 190 nm) and at this temperature the composite coarsens over a few days. The initial low thermal conductivity increases by 60% as the inter-lamellar spacing grows. Much of this increase is due to increased electrical conductivity.

Thermal conductivity is the sum of the lattice and electronic components. By subtracting the electronic component derived from resistivity measurements of transformed and untransformed material, we can deduce the lattice component. FIG. 6 shows a clear increase in thermal conductivity as the lamellar spacing increases from 250 nm to 300 nm. Above 300 nm the thermal conductivity levels off, indicating that interfacial phonon scattering no longer dominates the thermal transport. This suppression of the lattice thermal conductivity by approximately 25% to our knowledge has never been so clearly observed and suggests the theoretical predictions of phonon suppression through nanostructuring may prove true. Further reduction in lattice thermal conductivity should be observed for even finer microstructure (at least 180 nm spacing) which one may achieve with lower temperature anneals.

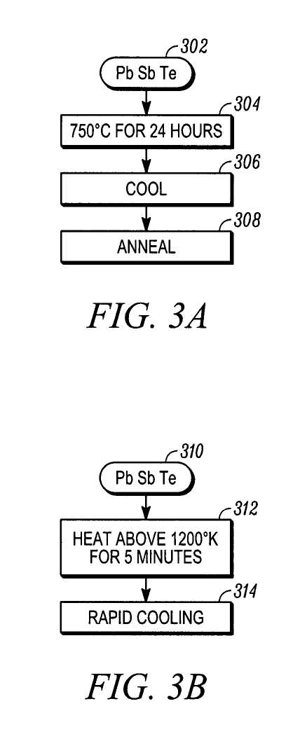

The process described above may be briefly summarized by the simplified flow diagram of FIG. 3A. Starting with Pb, Sb, Te in block 302, the mixture is heated for 24 hours at 750° C. in block 304, cooled in block 306, and then annealed in block 308. Annealing provides for decomposition of Pb₂Sb₆Te₁₁ into the desired PbTe and Sb₂Te₃ lamellae structures as described above.

Because the dramatic reductions in thermal conductivity offered by nanostructured materials is apparent for transport both parallel and perpendicular to the superlattices, and thus may not depend on grain to grain orientation, rapid solidification may be particularly well-suited to the fabrication of bulk, nanostructured thermoelectrics with enhanced zT. Some other embodiments of the present invention may be manufactured by rapid solidification of a liquid thermoelectric composite into self-assembled nanostructured thermoelectrics in bulk volume, where unlike the previous discussion, it is believed that the decomposition of the metastable Pb₂Sb₆Te₁₁ does not appear to play a major factor in the formation of the self-assembled structures.

Experiments were performed in which the effects of composition and cooling rate on the microstructures of alloys in the pseudo-binary PbTe—Sb₂Te₃ system were investigated. Liquid alloys of three different compositions were cooled in multiple distinct ways in fused silica ampoules: water quenching, air cooling, and furnace cooling. The resultant structures and phases were examined by electron microscopy, electron microprobe chemical analysis, and electron backscatter diffraction. The compound Pb₂Sb₆Te₁₁ precipitated as a metastable phase, in conjunction with PbTe and (or) Sb₂Te₃. Furthermore, whereas PbTe exhibited dendritic morphology, Sb₂Te₃ and Pb₂Sb₆Te₁₁ crystallized as lamellar platelets with preferred (001) orientation. The range of cooling rates was approximately from 1 to 26 K/s, and the characteristic microstructural feature size ranged from 10 to 35 μm for dendrites, and from 15 to 50 μm for lamella.

Alternatively, faster cooling may be achieved by using rapid solidification techniques such as injection molding, splat quenching, or tape casting. For example, injection molded samples have been produced using a copper mold.

Rapid solidification includes cooling a melt through a eutectic or slightly off-eutectic composition. Feature sizes, for example interlamellar spacing and secondary dendrite arm spacing, typically exhibit a power law dependence on an experimental parameter such as cooling rate, solidification time, or growth rate of the solid-liquid interface, with higher cooling rates producing finer microstructures. A wide variety of phase morphologies may be produced, from 2-dimensional lamella to 1-dimensional rods as well as complex dendritic features, which may or may not display preferred orientation between neighboring grains.

The nature of the chemical bonding in the PbTe—Sb₂Te₃, system suggests high viscosity in the liquid phase and low interfacial energies between solid phases, both features that favor fine microstructures.

Experiments were performed in which elemental Pb, Sb, and Te granules or powders (99.999% purity) of around 7 gram in total weight were sealed under vacuum in fused quartz tubes having a 10 mm inner diameter and 1.5 mm thick walls. Three alloy compositions were examined: Te-36 at. % Sb-5 at. % Pb (Alloy 1), Te-31.5 at. % Sb-10.5 at. % Pb (Alloy 2) and Te-24 at. % Sb-20 at.% Pb, labeled as Alloy 1, Alloy 2, and Alloy 3 in Table 1, respectively. These alloys may be located on the pseudo-binary PbTe—Sb₂Te₃ phase diagram. Alloy 2, corresponds to the eutectic composition Pb₂Sb₆Te₁₁ (=2PbTe—3Sb₂Te₃), whereas Alloys 1 and 3 are rich in Sb₂Te₃ and PbTe, respectively, relative to Alloy 2. The samples were melted by induction heating to temperatures above 1200 K for approximately 5 minutes and then cooled (while still in the fused quartz ampoules) by one of three methods: quenching in water, cooling in air, or cooling with the ampoules placed in a ceramic tube padded with thermal insulation. The third method is referred to as “furnace cooling.” The temperature variations during cooling were measured with W/Nb thermocouples (0.13 mm in diameter), which were located at the center of the ampoules. For Alloy 2, the temperature near the perimeter was also recorded. These experiments were performed in order to provide a direct measure of the cooling rate during solidification, and were carried out two to three times for each combination of cooling method and alloy composition.

The alloys so prepared were cut, mounted in epoxy pucks and polished with 0.3 μm Al₂O₃ paste. The microstructures were observed using a field emission-scanning electron microscope equipped with a backscattered electron (BSE) detector. The accelerating voltage was 20 kV. The microstructures were digitally analyzed using an image processing program. The chemical compositions of the constituent phases in each alloy were measured using an energy dispersive X-ray spectrometer, or using a wavelength dispersive X-ray spectrometer (WDS). For the WDS measurements, Sb, Te and Pb samples were used as standards for ZAF conversion from intensities of Pb M_{α}, Sb L_{α}and Te L_{α}to concentrations. The crystallographic orientations in the microstructures of air , cooled samples Alloy 1 and 2 were determined using electron backscatter diffraction technique (EBSD). For these measurements, the surfaces of the samples were finally polished with colloidal silica (50 nm). The operating voltage of the electron microprobe was 20 kV. The surface of the samples was inclined by 70° to the vertical direction with respect to the electron beam. Electron backscatter patterns over areas of 1,200×594 μm² were mapped using the steps of 6×6 μm² and analyzed using a commercial software package. Using this combination of methods, dimensional features of the microstructure were quantified, as were the volume fractions of the resulting phases and their crystallographic orientation relative to one another.

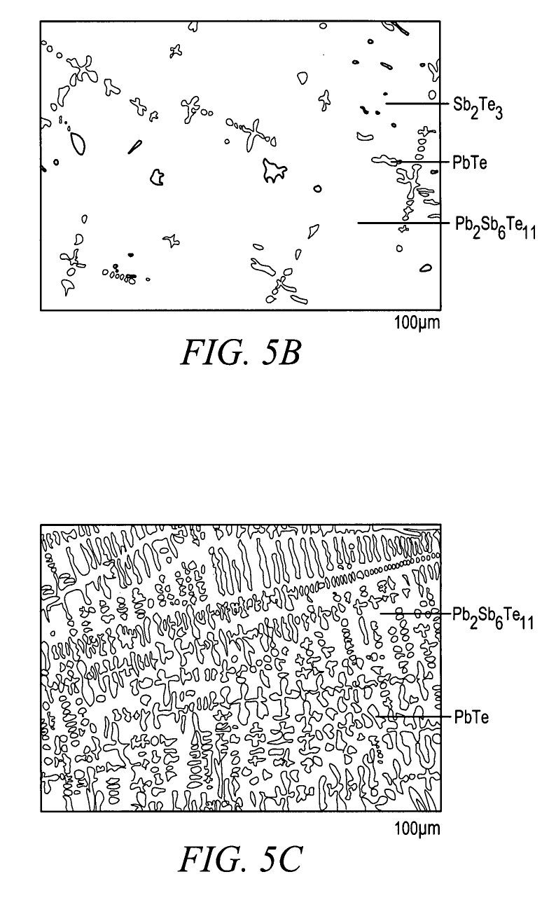

Scanning electron microscopy images (backscattered mode) of the microstructures obtained by air cooling and water quenching are shown in FIGS. 4A through 4C, and FIGS. 5A through 5C, respectively, where alloys 1, 2, and 3 correspond to the “A”, “B”, and “C” designations of the figures. The measured compositions are summarized in Table 2. Alloy 1 exhibits a lamellar structure composed of two phases. On the basis of the WDS analysis, the darker phase is identified as Sb₂Te₃, containing a small but measurable concentration of Pb. The Sb₂Te₃ exhibits a bimodal grain size distribution, but both large-grained and small-grained regions have similar composition, as indicated in Table 2. The lighter phase in Alloy 1 has a stoichiometry corresponding closely to that of Pb₂Sb₆Te₁₁. Alloy 2, which has an overall composition near that of the eutectic, is composed of three major phases. The bright dendritic phase is identified as PbTe containing a small but detectable concentration of Sb. The two-phase matrix in which these dendrites appear is a lamellar composite comprised of Pb₂Sb₆Te₁₁ and Sb₂Te₃, which, as in Alloy 1, contains a small but measurable concentration of Pb. Alloy 3 exhibits a strongly dendritic structure. As in Alloy 2, the bright dendritic phase (which is more prominent here) is PbTe containing a small amount of Sb. In contrast to Alloy 2, however, the matrix is almost entirely Pb₂Sb₆Te₁₁. The dark thin grains evident within the matrix were too small (<1 μm) for explicit examination by WDS methods, but are believed to correspond to Sb₂Te₃. For all three alloys, the differences in the phase compositions as a result of differences in cooling rates were insignificant, and thus only the results observed for air-cooled samples are summarized in Table 2.

In addition to the dominant phases listed in Table 2, small quantities of phases with compositions displaced from the pseudo-binary PbTe—Sb₂Te₃ towards the Sb-rich direction were also observed. In general, these compositions appeared within the dark regions of the backscattered electron images and it was difficult to distinguish them visually from the Sb₂Te₃ phase as a result of the similarity of the atomic weights of Sb and Te. As a consequence, although they were clearly present as minor components, the precise compositions and quantities of these phases were not accurately determined.

For Alloy 1, Sb₂Te₃ crystallizes from the melt forming large primary crystals, and then co-crystallizes with Pb₂Sb₆Te₁₁ at the eutectic temperature to yield smaller secondary crystals. For Alloys 2 and 3, dendritic PbTe crystallizes from the melt leaving a liquid with high Sb₂Te₃ content which finally crystallizes at the eutectic temperature to yield a mixture of Pb₂Sb₆Te₁₁ and Sb₂Te₃, with the Sb₂Te₃ content being greater for Alloy 2. Small quantities of Sb-rich phases appear because the eutectic point appearing in the pseudo-binary PbTe—Sb₂Te₃ system is the starting point of monovariant lines in the ternary Pb—Sb—Te system, which separate the primary crystallization fields of the Sb₂Te₃ and PbTe phases and move, respectively, in the Sb-rich and Te-rich directions with decreasing temperature. Therefore, in the late stages of solidification the composition of the liquid phase must deviate from the pseudo-binary PbTe—Sb₂Te₃ line towards either the Sb-rich or Te-rich direction along the monovariant lines, with deviations towards the Sb-rich direction apparently being more readily accommodated.

For these particular embodiments, the PbTe of Alloy 2, contains approximately 6 at % Sb, and the Sb₂Te₃ of Alloy 2, contains approximately 2.4 at % Pb, Thus, the solidified phases appear supersaturated with respect to the dissolved species as a result of the rapid cooling. In contrast, the Pb₂Sb₆Te₁₁ phase appearing in all three alloy compositions studied in these particular embodiments exhibits an extremely limited stoichiometry range and in all cases the measured composition is within error of the ideal stoichiometry.

In Table 2, the fraction of Sb₂Te₃ phase appearing in Alloy 1 and the fraction of PbTe appearing in Alloy 3 are shown as functions of the cooling method. The observed values are compared to those expected from the PbTe—Sb₂Te₃ system phase diagram (assuming Pb₂Sb₆Te₁₁ to be a line compound). It was also assumed that the Sb₂Te₃ and PbTe phases have solubilities of 1.5 at. % Pb and 2.9 at. % Sb, respectively. Overall, the measured phase fractions (for air cooling, 63±5% Sb₂Te₃ in Alloy 1 and 26±2% PbTe in Alloy 3) are close to those predicted from the phase diagram, with a slight trend towards decreasing Sb₂Te₃ content in Alloy 1 with increasing cooling rate.

The results of the EBSD analysis for Alloy 1 (air cooled, sample center), which, as described above, was comprised of lamellae of Sb₂Te₃ and Pb₂Sb₆Te₁₁. A similar analysis was also carried out for Alloy 2. The structure of Sb₂Te₃ is well known (R 3̅ m, a=0.4264 nm and c=3.0458 nm). In the case of Pb₂Sb₆Te₁₁, the structure has not yet been fully determined. A preliminary examination of the X-ray diffraction pattern obtained from water quenched samples of Alloy 2 (containing 99% Pb₂Sb₆Te₁₁) suggested that the structure of this compound is essentially that of PbSb₂Te₄ (R 3̅ m, , a=0.4350 nm and c=4.1712 nm).

A comparison of the regions identified by EBSD and by chemical analysis as being the Sb₂Te₃ phase and the Pb₂Sb₆Te₁₁ phase demonstrated excellent correspondence between the two techniques validating the use of the PbSb₂Te₄ structure to represent Pb₂Sb₆Te₁₁. Rather notable is the clear correspondence between the orientations of the Sb₂Te₃ grains and those of the Pb₂Sb₆Te₁₁ phase. Both of these compounds, having layered crystal structures, form platelets that extend perpendicular to the [001] axis. The grain morphology indicates that the (001) faces of both the phases are the directions of slower growth compared to growth perpendicular to (001). In addition, the platelet direction (001) of the Sb₂Te₃ and the Pb₂Sb₆Te₁₁ phases are oriented parallel to one another

Quantification of the microstructural features (FIGS. 4A through 4C, and FIGS. 5A through 5B) may be described as follows. The secondary dendritic arm spacing (SDAS) was selected as a characteristic feature for Alloys 2 and 3, whereas the interlamellar spacing was selected for Alloys 1 and 2. The analyses were performed on two to three images obtained from the sample centers for each cooling condition. In the case of the interlamellar spacing, the microstructural evaluation is influenced by the fact that the plate-like lamellae have a random orientation with respect to the image plane. As a consequence, both the average interlamellar spacing and the distribution of spacings appear greater than the physical reality. The SDAS decreases with increasing R_{LS} in both alloys, as expected, ranging in values from 20.2 μm to 12.0 μm for Alloy 2 and 23.7 μm to 12.1 μm in Alloy 3.

For the embodiments considered here, the SDAS of Alloy 2, which has a composition near that of the eutectic, is smaller than that of Alloy 3. This behavior occurs because the amount of solute that is rejected increases as the composition moves further away from the end-member and towards the eutectic and demonstrates that compositional tuning provides a means of controlling the characteristic microstructural length scale.

For lamellae formed from a simple eutectic reaction, it may be shown that the inter-lamellar spacing, ILS, depends on the solidification velocity, v, as well as on several material parameters according to

$${( ILS )}^{2} ∝ \frac{D {γ}_{α β} {V}_{m} {T}_{E}}{v Δ H} ,$$

where D is the diffusion coefficient, γ_{αβ}, the surface energy between the two solid phases, Vₘ, the molar volume, T_{E}, the eutectic temperature, and ΔH, the enthalpy of crystallization. Although it was not possible to evaluate the solidification velocities from the cooling curves, it is reasonable to expect that these velocities are correlated to the cooling rates, which is certainly indicated by the general decrease in ILS with increasing cooling rate.

It has been observed that the microstructural length scales may be manipulated both by changes in the alloy stoichiometry and by changes in the processing conditions. It appears that the interlamellar spacing is more sensitive to alloy composition than it is to cooling rate. In the case of Alloy 1, the presence of large primary grains of Sb₂Te₃ skews the average spacing towards large values. Thus, a high level of microstructural control may be achievable via optimal selection of the alloy stoichiometry.

FIG. 3B illustrates in a simple fashion processing steps for some of the embodiments described above. Starting with Pb, Sb, Te in block 310, the mixture is heated for 5 minutes at a temperature above 1200° K in block 312, and rapid cooling is applied in block 314. Embodiments were solidified in three distinct ways with cooling rates of about 1 to 26 Kelvin per second. Summarizing the above-described results, the compound Pb₂Sb₆Te₁₁ was found to precipitate, in conjunction with PbTe and (or) Sb₂Te₃, under all conditions for the above-described embodiments with the crystal structure of PbSb₂Te₄. PbTe (containing 6 at % Sb) exhibited a dendritic morphology, while Sb₂Te₃ (containing 2.4 at % Pb) and Pb₂Sb₆Te₁₁ crystallized as (001) lamellar platelets. The PbTe-rich alloy actually contained all three phases (Pb₂Sb₆Te ₁₁, PbTe, and Sb₂Te₃) with the Sb₂Te₃ phase existing as very thin (≦1 μm) intergrowths between the Pb₂Sb₆Te₁₁ lamella. The basal planes (001) of the Sb₂Te₃ and Pb₂Sb₆Te₁₁ in the lamellae have preferred crystallographic orientations parallel to each other.

The characteristic microstructural feature size (secondary dendrite arm spacing or interlamellar spacing) ranged from 10 to 35 μm for dendrites, and from 15 to 50 μm for lamella, with the smallest feature sizes being attained for alloys of the eutectic composition. The feature sizes varied with both cooling rate and starting composition.

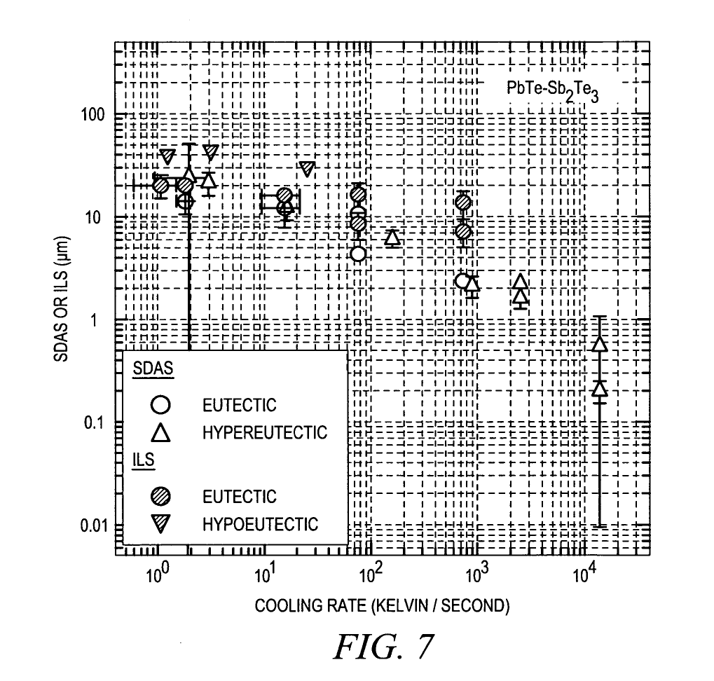

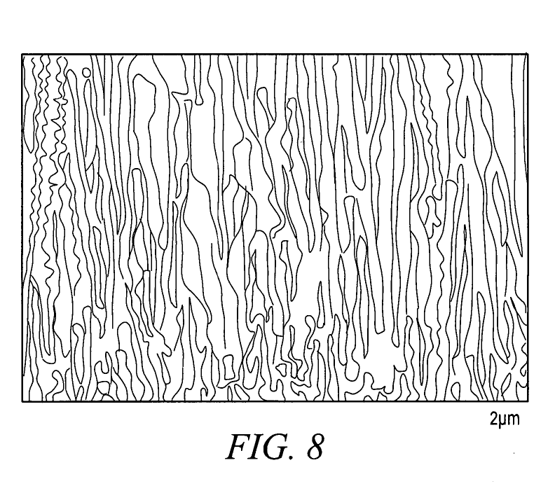

Embodiments have also been recently produced utilizing faster cooling rates using an injection molding procedure, with results provided in FIG. 7. FIG. 8 illustrates a micrograph of a resulting structure. (The light structures are PbTe and the dark structures are Pb₂Sb₆Te₁₁.) Note that from FIG. 8 the resulting features are dendrites as opposed to lamellae. From FIG. 7, it is seen that the spacing between the dendrites may be less than one micron for fast cooling rates.

An injection molding procedure may be described as follows. Alloys of Te-31.5 at. % Sb-10.5 at. % Pb (˜Pb₂Sb₆Te₁₁) and Te-24 at. % Sb-20 at. % Pb, were synthesized by melting pure Tellurium, Antimony, and Lead in quartz tubes by induction heating under vacuum. The mold material is Copper.

Small pieces of Te-31.5 at. % Sb-10.5 at. % Pb alloy or Te-24 at. % Sb-20 at. % Pb alloy of ˜15-20 g were put in a quartz tube, which had a small hole with ˜1 mm diameter, and were melted by induction heating under vacuum. When the alloy was melted, Argon gas with the pressure of 2 bar was introduced, and the alloys were injected into the mold. In some cases, the sample alloy in liquid state dropped from the quartz tube into the mold. In these cases, the injection pressure was defined to be 0 bar.

Microstructural observation by SEM was conducted at the regions around 10 μm and 100 μm from the sample surface and around the middle of the samples. The size scale of the microstructure (secondary dendrite arm spacing, SDAS, and inter-lamellar spacing, ILS).

Estimation of cooling rates in the injection molding was made using analytical expression of temperature variation with time and distance for plates. It was found that the cooling rate depends on the distance from the surface and the injection pressure. In the case where the injection pressure is 2 bar, where cooling rate is higher than 0 bar, the cooling rate was estimated to be from 1.5×10² K/s (in the middle of a sample with 3 mm thickness) to 1.4×10⁴ K/s (10 μm from the surface), while cooling in quartz tubes gave slower cooling rates, from 1 K/s (furnace cooling) to 15 K/s (water cooling).

The above description for forming thermoelectric material was based upon the pseudo binary system PbTe—Sb₂Te₃ of two thermoelectric. However, other embodiments may be based upon other thermoelectric Tellurides. Two such examples are embodiments based upon a GeTe—Sb₂Te₃ system, and a GeTe—Bi₂Te₃ system.

Sb₂Te₃ is intrinsically p-type due to anti-site defects (Sb on the Te sites), and PbTe may be either n-type or p-type. In the lamellar structures, the two phases are alloy with each other, resulting in Pb on the Sb sites, making the Sb₂Te₃ more p-type, and Sb on the Pb sites, making the PbTe n-type. The anti-site defects (Sb on Te sites) are particularly numerous in Sb₂Te₃, making Sb₂Te₃ particularly difficult to dope n-type. To reduce the p-type carrier concentration of Sb₂Te₃, it is typically alloyed with Bi₂Te₃. Unfortunately, Bi will also act as an n-type dopant for PbTe. Here, Bi substitutes for Pb, providing an additional source of n-type carriers for PbTe. Thus, these composites inherently consist of n-type and p-type regions. However, it is expected that a GeTe based system may be easier to tune in the sense that Ge may be doped with Ag to be made p-type. Sb₂Te₃ and Bi₂Te₃ are not doped by Ge, and are made either n-type or p-type by tuning the Sb or Bi ratio. As a result, it is expected that thermoelectrics in the GeTe—Sb₂Te₃ or GeTe—Bi₂Te₃ systems may be produced having only p-type lamellar structures, which may increase the Seebeck coefficients.

The constituent binary phases making up the GeTe—Bi₂Te₃ system are both good thermoelectric materials that exhibit some of the highest known zT figures of merit. A variety of layered ternary phases is known to exist which form the homologous series nGeTe:mBi₂Te₃, where 1≦n≦9 and 1≦m≦4, and these ternary compounds have been extensively characterized and exhibit good thermoelectric performance.

Embodiments in the GeTe—Bi₂Te₃ system form a single-phase ternary solid (crystalline or amorphous) which is not thermodynamically stable. Upon partitioning of the thermodynamically unstable ternary solid, the resulting lamellar spacing is expected to be dictated by the interfacial energy of the resulting phases. For initial compositions in the middle of the pseudo-binary system, the product phases will be ternary compounds from the nGeTe:mBi₂Te₃ homologous series. The lattice mismatch between these layered ternaries is much lower than for the PbTe—Sb₂Te₃ system (e.g., 0.3% for GeBi₄Te₇/Ge₂Bi₂Te₅ than the 6.5% for PbTe/Sb₂Te₃), which is expected to enable nanostructuring down to about 10 nm. It is expected that these structures are epitaxially oriented with clean interfaces as found in the PbTe/Sb₂Te₃, which should allow for high electron mobility. Similarly small lattice mismatches are expected to be found for the other ternaries in the GeTe/Bi₂Te₃ and GeTe/Sb₂Te₃ systems.

Various modifications may be made to the disclosed embodiments without departing from the scope of the invention as claimed below.

### TABLES

TABLE 1
Compositions of alloys used in some embodiments

| Alloy | Chemical | | Pseudo-binary | |
|---|---|---|---|---|
| No. | Formula | Composition | notation | |
| Alloy 1 | Pb₅Sb₃₆Te₅₉ | Te-36 at. % | 21.7 mol % | (PbTe) |
| | | Sb-5 at. % Pb | −78.3 mol % | (Sb₂Te₃) |
| Alloy 2 | Pb_{10.5}Sb_{31.5}Te₅₈ | Te-31.5 at. % | 40 mol % | (PbTe) |
| | or ˜Pb₂Sb₆Te₁₁ | Sb-10.5 at. % Pb | −60 mol % | (Sb₂Te₃) |
| Alloy 3 | Pb₂₀Sb₂₄Te₅₆ | Te-24 at. % | 62.5 mol % | (PbTe) |
| | | Sb-20 at. % Pb | −37.5 mol % | (Sb₂Te₃) |

TABLE 2
Composition of each phase observed in the Te—Sb—Pb alloys as measured by electron-probe micro-analysis
with a wavelength dispersive X-ray spectrometer for some embodiments. The average values of several
points in air cooled samples are listed. Errors were statistically estimated.

| Alloy | Nominal | | | | | |
|---|---|---|---|---|---|---|
| No. | composition | Phase | Te [at. %] | Sb [at. %] | Pb [at. %] | Fraction [%] |
| Alloy | Te-36 at. % | Gray | 57.25 ± 0.46 | 32.18 ± 1.84 | 10.57 ± 1.40 | 37 ± 5(a) |
| 1 | Sb-5 at. % Pb | Dark (Large grain) | 59.99 ± 0.52 | 38.12 ± 0.65 | 1.89 ± 0.14 | 63 ± 5(b) |
| | | (Closely spaced) | 59.31 ± 0.02 | 38.73 ± 0.19 | 1.96 ± 0.17 | |
| | | (Total) | 59.72 ± 0.83 | 38.36 ± 0.82 | 1.92 ± 0.15 | |
| Alloy | Te-31.5 at. % | Gray | 57.59 ± 0.15 | 31.78 ± 0.33 | 10.62 ± 0.48 | |
| 2 | Sb-10.5 at. % Pb | Bright | 52.09 ± 0.28 | 6.04 ± 0.13 | 41.87 ± 0.18 | |
| | | Dark | 57.12 ± 2.15¹ | 40.45 ± 1.79¹ | 2.43 ± 0.89¹ | |
| Alloy | Te-24 at. % | Gray | 57.25 ± 0.21 | 31.66 ± 0.26 | 11.10 ± 0.25 | 74 ± 2(c) |
| 3 | Sb-20 at. % Pb | Bright | 51.88 ± 0.13 | 2.67 ± 0.02 | 45.45 ± 0.11 | 26 ± 2(d) |

| | | | | |
|---|---|---|---|---|
| Theoretical composition | Sb₂Te₃ | 60.00 | 40.00 | 0.00 |
| | Pb₂Sb₆Te₁₁ | 57.89 | 31.5 | 10.52 |
| | PbTe | 50.00 | 80.00 | 50.00 |

¹Measured by energy dispersive X-ray spectrometry.
(a)39 expected from equilibrium phase diagram

(b) 61 expected from equilibrium phase diagram
(c) 74 expected from equilibrium phase diagram
(d) 26 expected from equilibrium phase diagram

What is claimed is:

1. An article of manufacture comprising a first thermoelectric material and a second thermoelectric material each having different crystallographic structures, wherein the first and second thermoelectric materials are arranged into structures having a periodic spacing less than ten microns.

2. The article of manufacture as set forth in claim 1, wherein the first and second thermoelectric materials have a specific epitaxial crystallographic orientation with respect to each other.

3. The article of manufacture as set forth in claim 1, wherein the first and second thermoelectric materials comprise Te.

4. The article of manufacture as set forth in claim 1, wherein the first thermoelectric material comprises PbTe and the second thermoelectric material comprises Sb₂Te₃.

5. The article of manufacture as set forth in claim 1, wherein the first thermoelectric material comprises GeTe and the second thermoelectric material comprises Sb₂Te₃.

6. The article of manufacture as set forth in claim 1, wherein the first thermoelectric material comprises GeTe and the second thermoelectric material comprises Bi₂Te₃.

7. The article of manufacture as set forth in claim 1, wherein the structures are lamellae structures.

8. The article of manufacture as set forth in claim 1, wherein the structures are dendrite structures.

9. An article of manufacture comprising a first thermoelectric material and a second thermoelectric material, wherein the first and second thermoelectric material are self-assembled structures.

10. The article of manufacture as set forth in claim 9, wherein the first and second thermoelectric materials comprise Te.

11. The article of manufacture as set forth in claim 9, wherein the first thermoelectric material comprises PbTe and the second thermoelectric material comprises Sb₂Te₃.

12. The article of manufacture as set forth in claim 9, wherein the first thermoelectric material comprises GeTe and the second thermoelectric material comprises Sb₂Te₃.

13. The article of manufacture as set forth in claim 9, wherein the first thermoelectric material comprises GeTe and the second thermoelectric material comprises Bi₂Te₃.

14. The article of manufacture as set forth in claim 9, wherein the structures are lamellae structures.

15. The article of manufacture as set forth in claim 9, wherein the structures are dendrite structures.

16. A method comprising:
heating a mixture of elements comprising Te into a melt;
cooling the melt; and
annealing the melt.

17. The method as set forth in claim 16, the mixture further comprising Pb and Sb.

18. The method as set forth in claim 16, the mixture further comprising Ge and Sb.

19. The method as set forth in claim 16, the mixture further comprising Ge and Bi.

20. A method comprising:
heating a mixture of elements comprising Te into a melt; and
cooling the melt at a rate greater than one degree Kelvin per second.

21. The method as set forth in claim 20, the mixture further comprising Pb and Sb.

22. The method as set forth in claim 20, the mixture further comprising Ge and Sb.

23. The method as set forth in claim 20, the mixture further comprising Ge and Bi.
